(19) United States
(12) Patent Application Publication
(10) Pub. No.: US 2007/0152310 A1
(43) Pub. Date: Jul. 5, 2007

(54) Electrical ground method for ball stack package

(75) Inventors: Philip R. Osborn, San Jose, CA (US); Teck-Gyu Kang, San Jose, CA (US); Ilyas Mohammed, Santa Clara, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/321,856

(22) Filed: Dec. 29, 2005

(51) Int. Cl. H01L 23/02

(52) U.S. Cl. 257/678

(57) ABSTRACT

A microelectronic package including a dielectric element with at least one conductive ground pad. The package may also include a microelectronic element with at least one ground contact exposed at a rear surface of the element. The ground pad and the ground contact are electrically connected to each other by an electrically conducting material.

### BACKGROUND OF THE INVENTION

Semiconductor chips normally are formed as small, flat bodies having a generally planar front surface, a generally planar rear surface, and edges extending between these surfaces at the boundaries of the front and rear surfaces. The thickness of the chip between its front and rear surfaces generally is far smaller than the length and width of the chip, i.e., the dimensions of the front and rear surfaces in the planes of these surfaces. Typically, the chip has contacts exposed at its front surface. Semiconductor chips commonly are provided in packages which protect the chip and facilitate handling and mounting of the chip to a larger circuit element such as a circuit board or other circuit panel. Certain types of chip packages include a rigid or flexible dielectric structure sometimes referred to as a “chip carrier” overlying the front or rear surface of the chip. The chip carrier has electrically conductive terminals. The contacts of the chip are electrically connected to the terminals. The terminals may be elongated posts projecting from the chip carrier, most commonly from the surface of the chip carrier facing away from the chip. A packaged chip can be mounted to a circuit panel by bonding or otherwise connecting the terminals to the contact pads of the circuit panel. In some cases, the chip carrier is approximately the same size as the front or rear surface of the chip itself, and most or all of the terminals are disposed in a region of the circuit panel overlying the chip surface. In other cases, the chip carrier is larger than the chip so that the chip carrier projects outwardly beyond the edges of the chip. The terminals on the chip carrier may be larger than the contacts on the chip itself, and may be spaced at a larger spacing distance or “pitch” than the contacts of the chip. Moreover, the terminals may be arranged so that they can be more readily engaged by test equipment than the contacts of the chip itself. Also, the chip carrier provides mechanical protection for the chip during handling and mounting operations. Certain chip packages are made with chip carriers having terminals in a region of the chip carrier projecting beyond the edges of the chip. Some of the terminals are exposed at the surface of the chip carrier facing away from the chip, and others are exposed at the opposite surface. Packages of this type can be used, for example, in a stacked module. In a stacked module, the packages are disposed one atop the other, so that the front surface of the chip in one package faces generally toward the rear surface of the chip in another package. The chip carriers extend between the adjacent chips in the stack of packages. The terminals on the various chip carriers are aligned with one another and joined to one another. Stacked arrangements of this type provide a compact mounting for multiple chips as, for example, semiconductor memory chips.

The chip generally includes a ground contact or mechanism that enables the chip to be grounded to an external device, such as a circuit panel. Often the mechanisms for grounding the chip to a circuit panel, for example, increase the height of the chip package and are costly to produce. Despite considerable effort in the art devoted to development of chip packages heretofore, still further improvement would be desirable. In particular, it would be desirable to reduce the cost of the packaged chips and provide a grounding mechanism that is easy to produce.

### SUMMARY OF INVENTION

One aspect of the present invention provides microelectronic packages. A microelectronic package according to the aspect of the invention provides a dielectric element having at least one conductive ground pad. The microelectronic package also includes a microelectronic element having a front surface facing toward the dielectric element and a rear surface facing away from the dielectric element. The microelectronic element may further include bonding contacts exposed at the front surface, which are electrically connected to circuitry within the microelectronic element. At least one ground contact is exposed at the rear surface of the microelectronic element. The package also preferably includes an electrically conducting material extending between the at least one ground contact and the at least one conductive pad such that the at least one ground contact is in electrical communication with the at least one conductive pad. The electrically conducting material may be an electrically conducting adhesive. In one preferred embodiment, the microelectronic element as discussed above includes edges extending between the front surface and the rear surface of the package. The electrically conducting material may extend across at least one edge of the microelectronic element

The dielectric element may also include a plurality of terminals and traces, at least one of the terminals being a ground terminal and at least one of the traces being a ground trace. The ground trace is preferably electrically connected to the conductive ground pad and the ground terminal. And at least some of the bonding terminals are electrically connected to at least some of the terminals and traces.

A further aspect of the invention provides an assembly including a microelectronic package as described above and a substrate. The substrate may include contact pads to which the terminals of the microelectronic package are connected. The substrate may be in the form of a second microelectronic package. In one embodiment, the two microelectronic packages are stacked on top of one another and at least some of the terminals of one package are electrically connected to at least some of the terminals of the other package.

Another aspect of the invention provides a microelectronic package, which includes a substrate, a first microelectronic element, an interposer and an electrically conductive material. The substrate includes a front face, a rear face and has a plurality of conductive features. The first microelectronic element has a front surface facing toward the substrate and bonding contacts exposed thereat. The bonding contacts are electrically connected to at least some of the conductive features. The first microelectronic element also includes a rear surface facing away from the substrate with at least one ground contact exposed at the rear surface.

The interposer may overlay the rear surface of the microelectronic element and desirably includes a first side facing the microelectronic element and the substrate. A second side of the interposer faces opposite the first side. The interposer also includes a plurality of conductive features. The electrically conductive material electrically connects the ground contact with at least one of the conductive features of the interposer. At least some of the conductive features of the substrate are electrically connected to at least some of the conductive elements of the interposer.

The conductive features of the interposer may include a plurality of interposer terminals with at least one of the interposer terminals being an interposer ground terminal. Also, the conductive features of the substrate include a plurality of substrate terminals, at least one of which is a substrate ground terminal that is electrically connected to the interposer ground terminal. Both of these terminals are preferably electrically connected to a ground contact of the microelectronic element.

The package may be stacked with another package to form an assembly. The interposers of each package may be connected to a substrate of the package stacked above.

In still yet another alternate embodiment of the present invention, an assembly may include a plurality of microelectronic packages. Each package having a dielectric element, and a microelectronic element. The packages are stacked one on top of the other so that the rear face of each microelectronic element faces toward the dielectric element of the neighboring package in the stack, other than either the top or bottom package. The ground contact the microelectronic element in each package other than an end package is connected to an electrically conductive feature of the neighboring package's dielectric element.

### BRIEF DESCRIPTION OF THE DRAWINGS

FIG. 1 is a diagrammatic sectional view of one embodiment of the present invention;

FIG. 2 is a diagrammatic top view of the embodiment of FIG. 1;

FIG. 3 is a diagrammatic sectional view of one embodiment of the present invention;

FIG. 4A is a diagrammatic sectional view of one embodiment of the present invention;

FIG. 4B is a diagrammatic sectional view of one embodiment of the present invention;

FIG. 5 is a diagrammatic sectional view of one embodiment of the present invention;

FIG. 6A is a diagrammatic top view of one embodiment of the present invention;

FIG. 6B is a diagrammatic sectional view of the embodiment of FIG. 6A;

FIG. 7 is a diagrammatic sectional view of one embodiment of the present invention;

FIG. 8 is a diagrammatic sectional view of one embodiment of the present invention;

FIG. 9 is a diagrammatic sectional view of one embodiment of the present invention;

FIG. 10 is a diagrammatic sectional view of one embodiment of the present invention;

FIG. 11A is a diagrammatic perspective view of one embodiment of the present invention; and

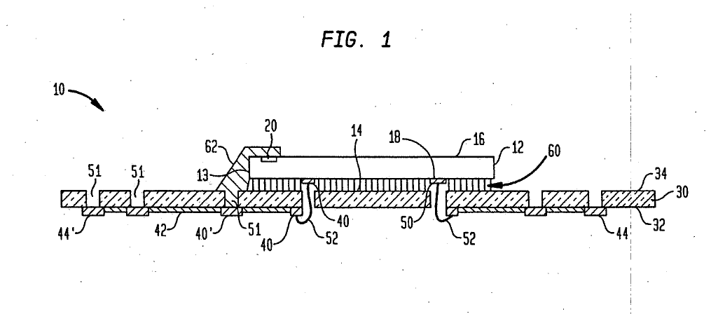

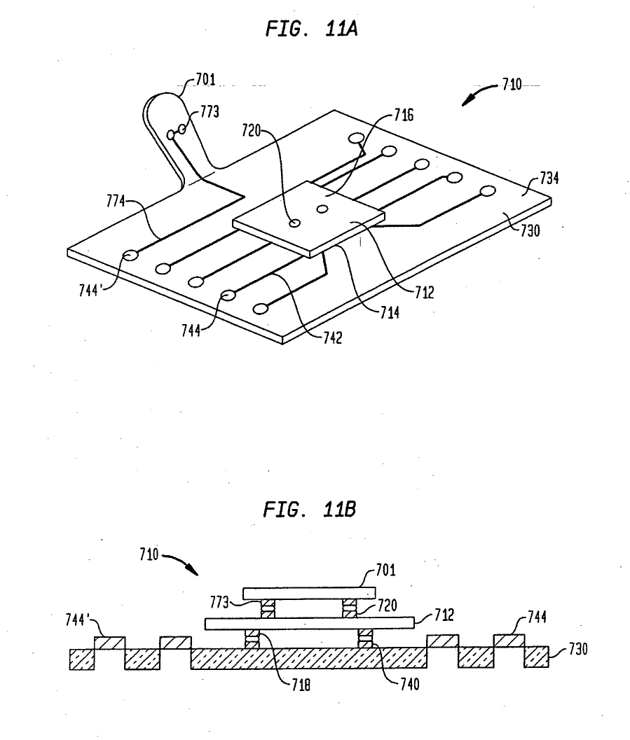

FIG. 1B is a diagrammatic sectional view of the embodiment of FIG. 11A.

### DETAILED DESCRIPTION

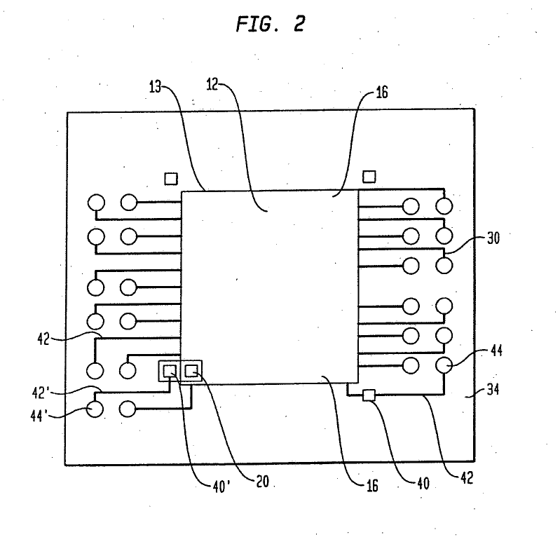

A component according to one embodiment of the present invention, as shown in FIGS. 1 and 2, includes a microelectronic package 10 having a first microelectronic element 12. The microelectronic element 12 has a front surface 14 facing downwardly and a rear surface 16 facing in an upward direction. As used herein, directional terms such as “up,” “down,” “upwardly,” “downwardly,” “upper,” “lower,” etc. do not refer to any gravitational frame of reference. Rather, these directional terms are relative to the package. An edge 13 extends around a perimeter of the microelectronic element 12 and between the front surface 14 and rear surface 16.

A plurality of bonding contacts 18 are exposed at the front surface 14 of the microelectronic element 12. The microelectronic element 12 also includes at least one ground contact 20 exposed at the rear surface 16. The ground contact 20 is specifically adapted for allowing the grounding of the microelectronic element 12 to an external feature, as will be described below. Merely by way of example, the ground contact may include a conductive ground plane connecting substantially the entire rear surface 16. Such a ground plane provides electromagnetic shielding for components within the chip and may also act to distribute the ground connection to the various circuits within the chip.

The microelectronic package 10 desirably includes a dielectric element 30 having a front face 32 and a rear face 34. The dielectric layer may be formed from any material suitable for forming a circuit panel substrate, or the like. For example, from the materials commonly used in forming flexible or rigid circuit panels such as polyimide, BT resin, glass-reinforced epoxy or the like. Most typically, the dielectric layer is on the order of 15 to 100 μm thick. The dielectric layer 30 desirably includes a plurality of conductive features, as for example, a plurality of ground pads 40′, conductive pads 40, traces 42, and terminals 44. At least some of the traces 42 are electrically connected to at least some of the terminals 44. The traces 42 include at least one ground trace 42′ connecting ground terminal 44′ and at least one ground pad 40′. In the particular embodiment depicted in FIGS. 1 and 2, the conductive features, i.e., conductive pads 40, ground pad 40′, traces 42, and terminals 44 are disposed on the front face 32 of the dielectric element, and the dielectric element 30 may also include a plurality of openings 51 extending from the front face 32 to the rear face 34 of dielectric element 30. The openings 51 enable at least some of the conductive features to be exposed at not only the front face 32 but also at the rear face 34 on the dielectric element 30. The dielectric element also includes openings or bond windows 50.

In a method of assembly, the microelectronic element 12 may be disposed overlying the dielectric layer 30 such that the front surface 14 of the microelectronic element 12 confronts the rear face 34 of the dielectric element 30. The rear surface 16 of the microelectronic element faces away from the dielectric element. Preferably, the bonding contacts 18 of the microelectronic element 12 are positioned adjacent to the bond windows 50. With the bonding contacts disposed adjacent to the bond windows 50, the bonding contacts 18 may be electrically connected to at least some of the traces 42 by an electrically conducting material 52 such as wire leads extending through the bond windows

Optimally, an adhesive layer 60 may be disposed between the front surface 14 of the microelectronic element 12 and the rear face 34 of the dielectric element 30.

Using an electrically conductive material 62, such as an electrically conductive adhesive or the like, the ground contact 20 may be electrically connected to one of ground pads 40′. This connects the ground contact 20 to one of the ground terminals 44′ via at least one trace 42′. By having the ground contact 20 electrically connected to the ground terminal 44′, the microelectronic,element 12 may be grounded to an external device as discussed herein.

In one method of assembly, the electrically conducting adhesive 62 extends at least partially over the rear surface 16 of the microelectronic element 12 and about the edge 13 of the microelectronic element. There is no need for extreme accuracy in placing the conductive adhesive so long as it covers some part of ground terminal 20 and some part of ground pad 40′ along exposed traces. In this embodiment, electrically conductive adhesive extends into an opening 51 in the dielectric element in order to electrically connect the ground conductive pad 40′ with the ground contact 20.

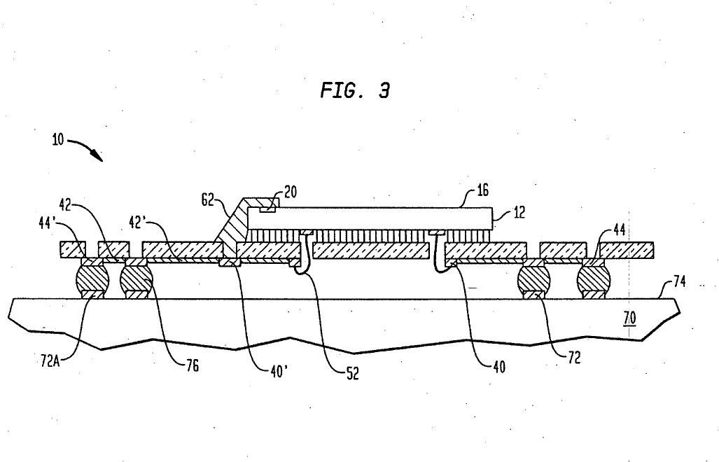

As shown in FIG. 3, the microelectronic package 10 may be coupled to a substrate or additional circuit panel 70. The circuit panel 70 may include a plurality of contacts 72 exposed at a surface 74 of the circuit panel. The microelectronic package 10 may be electrically connected to the circuit panel 70 by disposing an electrically conductive material 76, such as solder paste or the like in between at least some of the adjacent terminals 44, 44′ of the microelectronic package 10 and contacts 72 of the circuit panel 70. Contacts 72 include a ground contact 72A, which is coupled to the ground terminal 44′ of the package. Thus, the ground contact 20 of microelectronic element 12 is electrically connected to the circuit panel 70 by the electrically conductive material 62, ground pad 40′, a trace 42′, and ground terminal 44′, which are all electrically connected to a contact 72A of the circuit panel. This particular configuration enables the microelectronic package 10 to be connected to a circuit panel 70 and grounded to the circuit panel, while still maintaining a relatively low height profile. Also, the ground connection to ground contact 20 is provided at a very low cost.

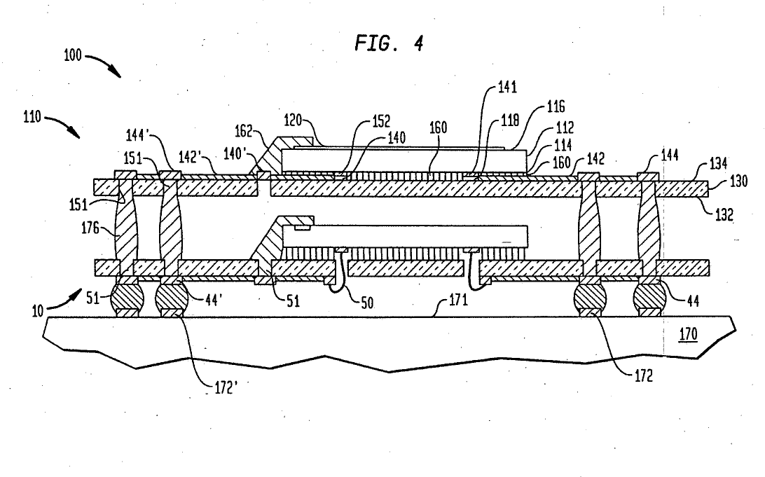

As shown in FIG. 4, the microelectronic package 10 may be coupled and/or stacked to a second microelectronic package 110 to form a microelectronic assembly 100. The second microelectronic package 110 is similar to the microelectronic package 10 except that in second package 110, the conductive elements such as terminals 144, traces 142 and ground pad 140′ are carried on the rear or chip-facing surface 134 of dielectric element 130. Stated another way, the second package 130 is in a “circuits-in” configuration in contrast to the “circuits-out” configuration of package 10. Because the conductive features of package 110 are carried on the rear or chip-facing surface 134 of the dielectric element 130, the dielectric element 130 does not require bond windows or openings as used in microelectronic package 10 to expose the conductive features at the rear surface 134. The bonding contacts 118 of the microelectronic element 112 are bonded directly to pads 140 provided on some of the traces 142. Here again, the ground pad 140′ is connected to the ground contact 120 on the rear surface 116 of the microelectronic element by a mass of conductive material 162 extending over the ground pad and extending upwardly, away from dielectric layer 130 onto the rear surface of the microelectronic element. Here again, the ground pad 140′ is connected by one or more ground traces 142′ to one or more ground terminals 144′. Openings 151 in the dielectric layer are provided in alignment with the terminals 144, including ground terminal 144′, so that the terminals are exposed at the front surface 132 of the dielectric element as well as at rear surface 134.

The terminals 144, 144′ on the second microelectronic package 110 may be electrically connected to the corresponding terminals 44, 44′ of the first microelectronic package 10 with the use of electrically conductive elements such as a solder ball and/or paste 176 to form the microelectronic assembly 100. Alternatively, the terminals of the two packages may include mating elements such as pins and sockets.

The ground terminals 44′, 144′ of the two packages 10, 110, desirably are positioned such that when the microelectronic packages 10 and 110′ are assembled together to form microelectronic assembly 100′, the ground terminals are aligned with one another and connected to one another to thereby interconnect the ground contacts 20, 120 of the microelectronic packages 10, 110′ in the microelectronic assembly into a common ground connection.

The entire microelectronic assembly 100′, as well as microelectronic assembly 100, may be connected or attached to a substrate or a circuit panel 170. The circuit panel 170 may include contact pads 172 exposed at a surface 171 of the circuit panel 170. The contact pads 172 may be electrically connected to the terminals 44, 44′ of the bottom microelectronic package 10 of microelectronic assembly 100′ by an electrically conductive material such as solder 176, solder paste or the like and hence also connected to the terminals 144, 144′ of top package 110. In the embodiment of FIG. 4, since all of the ground terminals 44′, 144′ are aligned in a row, they may be interconnected to a single ground contact 172′ exposed on the surface 171 of the circuit panel 170.

The stacked assembly of FIG. 4A includes two packages 10 and 110 of two different configurations. More than two packages may be stacked in the same manner. Also, all packages may have the same configuration. For example, all may have the circuits-out configuration of package 10, or all may have the circuits-in configuration of package 110. Also, the particular connections between the bonding contacts of the microelectronic elements and the conductive features of the package substrates shown above are merely illustrative; any suitable connection may be employed. Moreover, although the packages discussed above have conductive features on surfaces of the dielectric elements, the conductive features may be disposed within the interiors of the dielectric elements and may include multiple layers of conductive features. For example, separate terminals may be provided at the front and rear surfaces of the dielectric elements, and may be connected to one another by conductive structures such as via liners extending through the dielectric elements. The microelectronic elements in the various packages may be the same or different. Also, the ground contact pad and associated conductive material may be omitted in one or more of the packages.

In contrast to FIG. 4A, FIG. 4B illustrates two microelectronic packages 10b and 10b that have the same configuration and are stacked on top of one another. For example, the ground terminals 44b′ and 144b′ as well as ground traces 42b′ and 142b′ are all exposed at a front surface 32b, 132b of respective dielectric elements 30b and 130b. In contrast, in FIG. 4A, the respective conductive features of each microelectronic package 10, 110 are exposed at opposite surfaces of the respective dielectric elements.

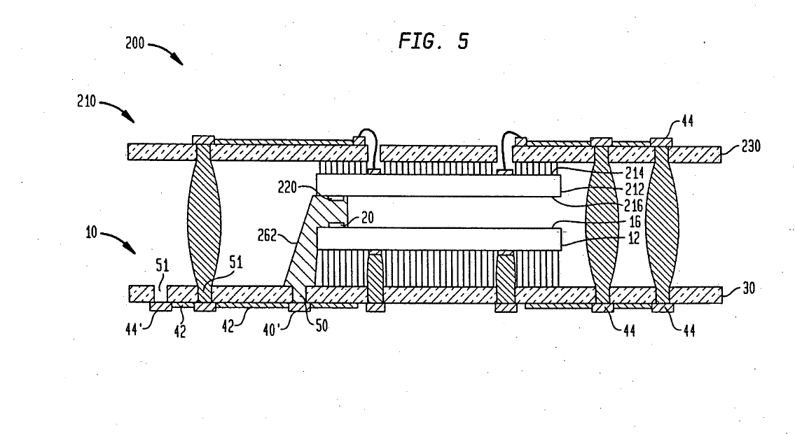

In yet another alternate embodiment of the present invention (FIG. 5), the microelectronic package 10 may be coupled to and stacked with microelectronic package 210 to form microelectronic assembly 200. Microelectronic package 210 is similar to the microelectronic packages discussed above.

Thus, microelectronic package 210 includes a microelectronic element 212 having a front face 214 and a rear face 216 as well as a dielectric element 230. The microelectronic element 212 may include at least one ground contact 220 exposed at a rear surface 216 of the microelectronic element 212. The other electrically conductive features of the microelectronic package 210 are similar to the electrically conductive features of the packages mentioned above and thus will not be discussed in detail.

In the stacked assembly when the microelectronic package 210 is coupled to microelectronic package 10, the rear surfaces 16 and 216 of microelectronic elements 12 and 212 confront one another. Since the microelectronic elements 12 and 212 are arranged such that their rear surfaces 16, 216 confront one another, the ground contacts 20, 220 disposed on respective rear surfaces 16, 216, also confront one another. In this manner, an electrically conductive adhesive 262 or other conductive materials may be disposed onto the ground contacts 20, 220 and extend to ground conductive pad 40′ of the microelectronic package 10 to thereby electrically connect the ground contacts 20, 220 to the ground conductive pad 40′. As with earlier embodiments, the ground conductive pad 40′ may be electrically connected to the ground terminal 44′ via a trace 42′. Although not shown in the figures, as with previous embodiments, the microelectronic assembly 200 may be electrically connected to a substrate or additional circuit panel.

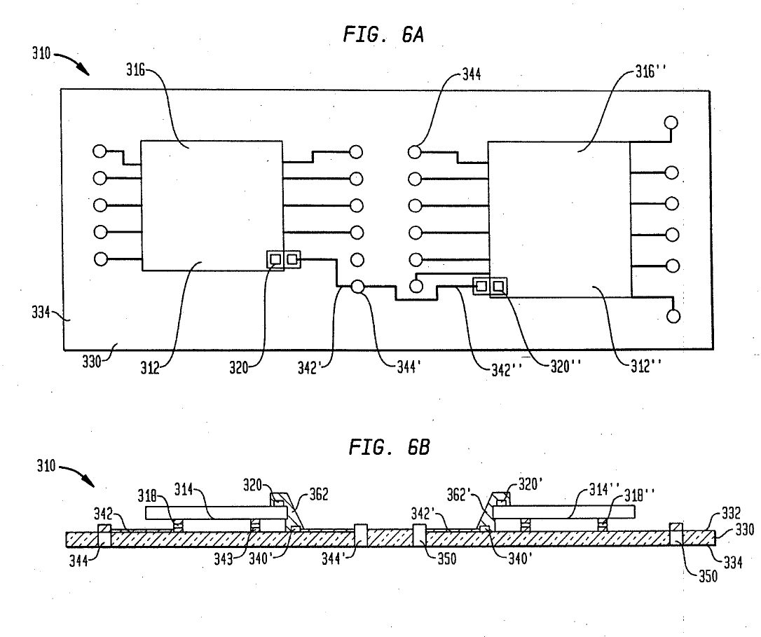

A microelectronic package 310 (FIGS. 6a and 6b) is similar to the package 10 discussed above with reference to FIGS. 1 and 2, except that in package 310, the traces 342, ground pad 340′ and terminals 344 are disposed on the rear or chip-facing side of the dielectric layer 332. Stated another way, the embodiment of FIG. 6 is a “circuits-in” arrangement. Also, the bond pads 318 of the microelectronic element 312 are bonded to at least some of the traces using masses of solder or other electrically-conductive bonding material. Thus, there is no need for an opening in the dielectric layer in alignment with the ground pad 340 and no need for a bond window to connect the contact pads of the microelectronic element with the traces. Openings 350 extend through the dielectric layer in alignment with terminals 344, so that the terminals are exposed at the front face 334 of the dielectric element, as well as at the rear face 332.

Here again, the terminals 344 include a ground terminal 344′, and the traces include a ground trace 342′ connected to the ground terminal. The electrically conductive features carried by the dielectric layer include a ground pad 340′ which is connected by the ground trace 342′ to the ground terminal. As in the embodiment of FIGS. 1 and 2, an electrically conductive adhesive extends between the rear face 316 of the microelectronic element and the ground pad, and connects the ground contact 320 of the microelectronic element with the ground pad 340′.

The package of FIGS. 6A and 6B also include a second microelectronic element 312″, which is mounted in the same manner as the first microelectronic element 312, and which has bonding contacts 318″ connected to at least some of the traces and terminals. A second ground pad 340″ is electrically connected to ground terminal 344′ by a second ground trace 342″. A second mass of electrically conductive material 362″ extends to the rear surface of the second microelectronic element, and connects a ground contact 320″ exposed at such rear surface to the second ground pad 340″ and hence to ground terminal 344′.

The package of FIGS. 6A and 6B may be incorporated in stacked structures and connected to a circuit panel (not shown) in substantially the same manner as discussed above. In further variants (not shown) more than two microelectronic elements may be provided on the same dielectric element. In a further variant, a single ground pad may be connected to the ground contacts of two or more microelectronic elements by a single large mass or pattern of electrically conductive material extending onto the rear surfaces of both microelectronic elements and also extending to the single ground pad. Conversely, the dielectric element may have two or more separate ground terminals connected to two or more separate ground pads.

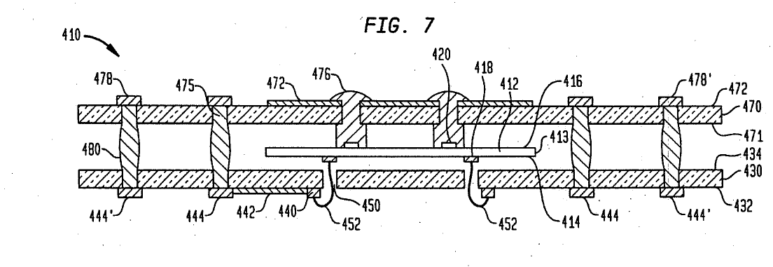

In yet another alternate embodiment of the present invention (as shown in FIG. 7), a microelectronic package 410 may include a microelectronic element 412, a substrate 430, e.g. dielectric element, and an interposer 470. The interposer 470 may be comprised of a similar material as the dielectric element discussed herein, such as a BT resin, polyimide or the like.

As with previous embodiments, the microelectronic element 412 may include a front surface 414 facing toward dielectric element 430, a rear surface 416 facing away from the dielectric element and an edge 413 extending between the two. A plurality of bonding contacts 418 may be exposed at the front surface 414 of the microelectronic element 412. The microelectronic element 412 may also include at least one, and as shown in FIG. 7, a plurality of ground contacts 420 exposed at the rear surface 416. Similar to previous embodiments, the ground contacts 420 are adapted for enabling the microelectronic element 412 to be grounded to an external device.

The substrate 430 may be disposed underlying the microelectronic element 412 such that a rear face 434 of the substrate 430 confronts the front surface 414 of the microelectronic element. As discussed with regard to previous embodiments, the substrate 430, e.g., dielectric element, may include various conductive features exposed at its rear face 434 or, as shown in the FIG. 7, a front face 432 of the substrate 430. The conductive features may include conductive pads 440, traces 442 and terminals 444. As with previous embodiments, at least some of the conductive elements may be electrically connected to some of the bonding contacts 418 of the microelectronic element via wire leads 452 that extend through bond windows 450. Here again, any other suitable attachment can be used to connect the bonding contacts to the traces.

The interposer 470 may be positioned overlying the microelectronic element 412 such that it confronts the rear surface 414 of the microelectronic element. The interposer 470 may include a first side 471 and a second side 472. In one embodiment, the first side 471 confronts the rear surface 416 of the microelectronic element 412. A plurality of ground conducting elements 473 may be exposed at either the first side of the interposer or, as shown in FIG. 7, at the second side 472 of the interposer. In such a case where the ground conducting elements 473 are exposed on the second side 472 of the interposer 470, the interposer 470 may include a plurality of apertures 475 extending from the first side 471 to the second side 472. The interposer also has terminals 478 including one or more ground terminals 478′.

An electrically conductive material 476 may be disposed onto the ground contacts 420 and extend into communication with the ground conducting features 473. The ground conducting features 473 may be further electrically connected to ground terminal 478′.

Terminals 478 and 478′ on the interposer are electrically connected to terminals 444 and 444′ disposed on substrate 430 via an electrically conductive material such as a solder paste 480 or other suitable connection, with ground terminal 478′ on the interposer connected to ground terminal 444′ on the substrate.

Although not shown in the drawings, as with previous embodiments, the microelectronic package 410 may be attached and electrically connected to a circuit panel or additional substrate.

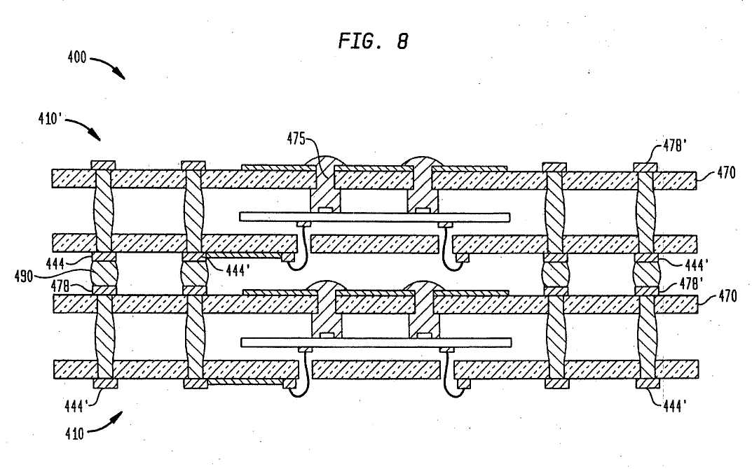

In a method of forming a microelectronic assembly 400, the first microelectronic package 410 may be stacked onto and electrically connected to a second microelectronic package 410′ as shown in FIG. 8. The second microelectronic package 410′ may be substantially identical to microelectronic package 410. In order to electrically connect the two microelectronic packages 410, 410′, an electrically conductive material, such as solder 490, may be used to interconnect terminals 444 and ground terminals 444′ of the top package 410′ with terminals 478 and 478′ on the interposer 470 of the bottom package.

The microelectronic assembly 400 may also be attached to an additional circuit panel or substrate. In a preferred embodiment, as shown in FIG. 8, ground terminals 444′ and 478′ may all be aligned together to form a common vertical ground bond.

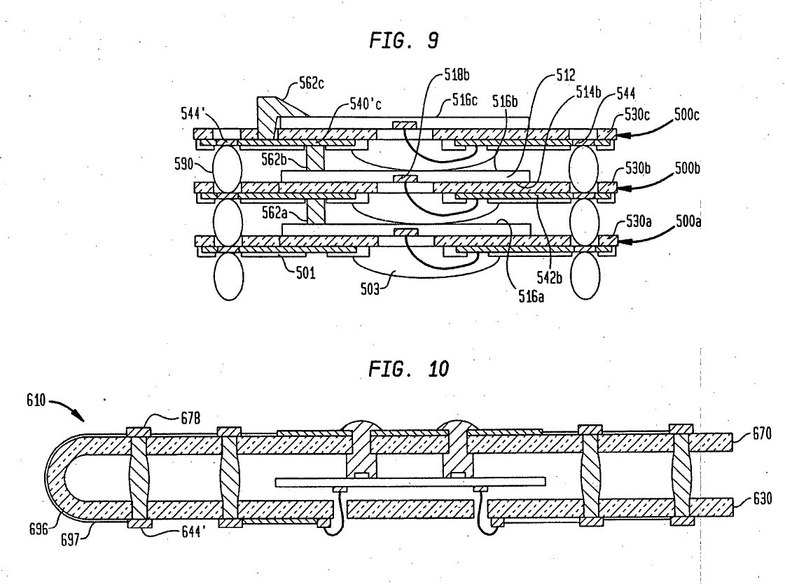

In a further variant, as shown in FIG. 9, an assembly may include a stack of packages 500, each including a dielectric element 530 having conductive features including terminals 544, 544′. The packages are stacked one atop the other and the terminals are interconnected to one another by conductive elements 590 as, for example, solder balls. Here again, the front surface 514 of the microelectronic element 512 in each package faces toward the dielectric element of that package. For example, in the middle package 500b, the front surface 514b of element 512b faces dielectric element 530b, and the bonding terminals 518b are electrically connected to traces 542b on dielectric element 530b. However, the rear surface 516 of each microelectronic element is electrically connected to a ground conductive feature on the dielectric element of the next higher package in the stack. For example, the rear surface 516b of microelectronic element 512b in middle package 500b is connected to a ground conductive feature 540c on dielectric element 530c of the next higher package by a mass of electrically conductive material 562b. Likewise, rear surface or grounding contact 516a of the bottom package 500a is connected by a mass of conductive material 562b to a ground conductive feature 540b on the dielectric element 530b of the middle package.

The top package 500c may include a different grounding arrangement, such as a further mass of conductive material 562c connecting the rear surface 516c of its microelectronic element to the ground conductive feature 540c on dielectric element 530c. The masses of conductive material may be applied during assembly of the packages to one another. Suitable solder masking 501 and dielectric encapsulants 503 are provided so that the masses of conductive material cannot contact conductive features other than the ground conductive features. The inverse arrangement, with the rear surface ground contact of each microelectronic element connected to a conductive feature on the next-lower package in the stack, can also be employed. Here again, the ground conductive features 540 of the various packages are connected to ground conductive terminals, which in turn are connected to one another.

In another aspect of the present invention, as shown in FIG. 10, a microelectronic package 610 may be similarly designed to microelectronic package 410 except that microelectronic package 610 includes a fold portion 696. Fold portion 696 is an extension of substrate 630 as well as interposer 670 thereby connecting the two elements in an integral fashion. The fold portion 696 preferably includes a ground trace 697 electrically connecting ground terminal 644′ of substrate 630 to ground terminal 678 of interposer 670. By electrically connecting the ground terminals 644′ to the ground terminal 678, the requirement for the ground terminals 678, 644′ to be electrically connected using an electrically conductive material, is eliminated. Optionally, such a conductive material can be provided.

In another alternate embodiment of the present invention, as shown in FIGS. 11A and 11B, a microelectronic package 710 may include a microelectronic element 712 and a substrate 730. The microelectronic element 712 may be similarly constructed as microelectronic element 12, discussed herein and include at least one or, as shown in the figure, a plurality of ground contacts 720 exposed at a rear surface 716 of the microelectronic element. The microelectronic element 712 may be disposed adjacent the substrate 730 such that a front surface 714 of the microelectronic element confronts a rear face 734 of the substrate. The microelectronic element 712 may include a plurality of bonding contacts 718 electrically connected to conductive pads 740 on the substrate 730. The bonding contacts 718 and the conductive pads 70 may be connected using methods discussed herein as well as methods known to those in the art.

Similar to previous embodiments, the conductive pads 740 of the substrate 730 may be connected to traces 742, which are additionally connected to terminals 744.

The substrate 730 may also include a flap 701, which extends outwardly from the substrate as shown in FIG. 11A. The flap 701 preferably includes ground conductive pads 773 electrically connected to ground traces 774. The ground traces 774 may extend from the flap 701 to the main portion of the substrate 730 and electrically connect to a ground terminal 744′.

In a method of assembly as shown in FIG. 11B, the flap 701 may be folded over such that it overlies the microelectronic element 712. Desirably, the ground conductive pads. 773 of the flap 701 are aligned with the ground contacts 720 of the microelectronic element 712 when the flap is folded. An electrically conductive material such as an electrical adhesive may be disposed between the ground contacts 720 and ground conductive pads 773 to thereby place the two features into electrical communication.

As with previous embodiments, once the microelectronic package 710 has been formed, it may be coupled to an external device such as a substrate or circuit panel with ground terminals 744′ being electrically connected to an external ground device.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic package comprising:
a dielectric element having at least one conductive ground pad;
a microelectronic element having a front surface facing toward said dielectric element, a rear surface facing away from said dielectric element, bonding contacts exposed at said front surface electrically connected to circuitry within the microelectronic element and at least one ground contact exposed at said rear surface; and
an electrically conducting material extending between said at least one ground contact and said at least one conductive pad such that said at least one ground contact is in electrical communication with said at least one conductive pad.

2. The microelectronic package according to claim 1, wherein said electrically conducting material is an electrically conducting adhesive.

3. The microelectronic package according to claim 1, wherein said dielectric element includes a plurality of terminals and traces, at least one of said terminals being a ground terminal, at least one of said traces being a ground trace electrically connecting said conductive ground pad and said ground terminal, at least some of said bonding terminals of said microelectronic element being electrically connected to at least some of said terminals and traces.

4. The microelectronic package according to claim 3, wherein said dielectric element has a rear surface facing toward said microelectronic element and a front surface facing away from said microelectronic element, said at least one conductive ground pad being remote from said rear surface, said dielectric element having a via extending from said rear surface to said conductive ground pad, said conductive material extending from said ground contact into said via to said conductive ground pad.

5. An assembly including the microelectronic package according to claim 3, the assembly further comprising a substrate having contact pads, said terminals of said microelectronic package being connected to said contact pads of said substrate.

6. An assembly including the microelectronic package according to claim 3 and a second microelectronic package connected to said terminals.

7. The microelectronic package according to claim 1, wherein said microelectronic element has edges extending between its front and rear surfaces and said electrically conducting material extends across at least one said edge of said microelectronic element.

8. The microelectronic package according to claim 1 wherein said electrically conducting material is an adhesive.

9. A microelectronic assembly comprising:
at least two microelectronic packages according to claim 3 stacked on top of one another, at least some of said terminals of one package electrically connected to at least some of said terminals of said other package.

10. A microelectronic package comprising:
a substrate having a front face and a rear face, said substrate also having a plurality of conductive features;
a first microelectronic element having a front surface facing toward said substrate, bonding contacts exposed at said front surface and electrically connected at least some of said conductive features, a rear surface facing away from said substrate, and at least one ground contact exposed at said rear surface;
an interposer overlying said rear surface of said microelectronic element, said interposer having a first side facing toward said microelectronic element and said substrate, a second side facing away from said microelectronic element and said substrate, and a plurality of conductive features; and
an electrically conductive material electrically connecting said at least one ground contact of said first microelectronic element with at least one of said conductive features of said interposer;
wherein at least some of said conductive features of said substrate are electrically connected to at least some of said conductive elements of said interposer.

11. The microelectronic package according to claim 10, wherein said electrically conductive material is an electrically conductive adhesive.

12. The microelectronic package according to claim 10, wherein said conductive features of said interposer include a plurality of interposer terminals, said interposer terminals including at least one interposer ground terminal, and said conductive features of said substrate include a plurality of substrate terminals including at least one substrate ground terminal electrically connected to said interposer ground terminal, said at least one ground contact of said microelectronic element being electrically connected to said interposer ground terminal and said substrate ground terminal.

13. The microelectronic package according to claim 12, wherein at least some of said bonding contacts are electrically connected to at least some of said substrate terminals and at least some of said interposer terminals.

14. The microelectronic package according to claim 13 wherein said substrate terminals and said interposer terminals are electrically connected to one another, said substrate ground terminal being electrically connected to said interposer ground terminal.

15. The microelectronic package according to claim 14 wherein said substrate and said interposer are formed from a unitary sheet of dielectric material having a fold therein.

16. The microelectronic package according to claim 14 further comprising conductive elements extending between said substrate and said interposer and electrically connecting said substrate terminals with said interposer terminals.

17. An assembly including a plurality of microelectronic packages according to claim 9 stacked one atop the other, with the interposer of each said package other than a top package in the stack being connected to the substrate terminals of a next higher package in the stack.

18. An assembly including a plurality of microelectronic packages, each said package including:
(a) a dielectric element having electrically conductive features,
(b) a microelectronic element having a front face facing toward the dielectric element of the package and a rear face facing away from the dielectric element of the package, bonding contacts exposed at the front face of the microelectronic element electrically connected to the conductive features of the package, and a ground contact exposed at the rear face of the microelectronic element,
said packages being stacked on one another so that the rear face of the microelectronic element of each package in the stack other than an end package faces toward the dielectric element of a neighboring package in the stack, the ground contact of the microelectronic element in each package other than the end package being electrically connected to the electrically conductive features on the dielectric element of the neighboring package.

19. An assembly according to claim 18 further comprising masses of electrically conductive material disposed between the rear face of each microelectronic element other than the microelectronic element of the end package and an electrically conductive feature of the dielectric element of a neighboring package, said electrical connections of said ground contacts including said masses of electrically conductive material.

20. An assembly according to claim 18 wherein said electrically conductive features of each package include terminals, the terminals of the packages in the stack being electrically connected to one another.

21. An assembly according to claim 20 wherein the terminals of each said package include a ground terminal and the ground terminals of the packages in the stack are electrically connected to one another.

22. The microelectronic assembly according to claim 21, wherein said electrically conductive material is an electrically conductive adhesive.
